(19) United States
(12) Patent Application Publication
(10) Pub. No.: US 2024/0128145 A1
(43) Pub. Date: Apr. 18, 2024

(54) SEMICONDUCTOR PACKAGES AND METHOD FOR FABRICATING THE SAME

(71) Applicant: SAMSUNG ELECTRONICS CO., LTD., SUWON-SI (KR)

(72) Inventors: HYEONSEOK LEE, SUWON-SI (KR); DONGKYU KIM, SUWON-SI (KR); HYEONJEONG HWANG, SUWON-SI (KR)

(21) Appl. No.: 18/469,111

(22) Filed: Sep. 18, 2023

(30) Foreign Application Priority Data
Oct. 17, 2022 (KR) 10-2022-0133212

(51) Int. Cl. H01L 23/367; H01L 21/306; H01L 21/308; H01L 21/48; H01L 21/56; H01L 23/00; H01L 23/31; H01L 23/373; H01L 23/498; H01L 25/065; H01L 25/10; H10B 80/00

(52) U.S. Cl. CPC H01L 23/367; H01L 21/30608; H01L 21/3086; H01L 21/4878; H01L 21/561; H01L 21/565; H01L 23/3107; H01L 23/3738; H01L 23/49822; H01L 24/16; H01L 24/95; H01L 25/0655; H01L 25/105; H10B 80/00; H01L 2224/16227; H01L 2224/16238; H01L 2224/95; H01L 2225/1023; H01L 2225/1041; H01L 2225/1058; H01L 2225/1094; H01L 2924/15174; H01L 2924/3511

(57) ABSTRACT

A semiconductor package includes a redistribution substrate, a sub-package disposed on the redistribution substrate, a semiconductor chip disposed on the redistribution substrate, a heat dissipation structure disposed on the redistribution substrate and surrounding the sub-package and the semiconductor chip, and an encapsulant. The redistribution substrate includes a redistribution structure. The semiconductor chip is positioned side-by-side with the sub-package. The encapsulant encapsulates the sub-package, the semiconductor chip, and the heat dissipation structure.

### CROSS-REFERENCE TO RELATED APPLICATION

This application claims priority under 35 U.S.C. 119 to Korean Patent Application No. 10⁻²⁰²²-0133212, filed on Oct. 17, 2022, the disclosure of which is incorporated by reference herein in its entirety.

### TECHNICAL FIELD

Embodiments of the present disclosure relate to a fan-out package and a manufacturing method thereof.

### DESCRIPTION OF THE RELATED ART

Package-on-package (POP) technology, which stacks an upper semiconductor package on top of a lower semiconductor package, may be used to integrate more passive or active devices into a given region.

The package-on-package technology involves electrically coupling a semiconductor chip to a front side redistribution line (FRDL) structure, molding it to form a fan out wafer level package (FOWLP), forming a back side redistribution line (BRDL) structure on the FOWLP, and connecting the upper semiconductor package to the top of the FOWLP through a redistribution line. Such package-on-package technology has a structural characteristic in which the front redistribution structure and substrate are disposed under the molded semiconductor chip, and the back side redistribution line structure and upper semiconductor package are disposed on the top of the molded semiconductor chip.

### SUMMARY

According to some embodiments of the present disclosure, a semiconductor package includes a redistribution substrate including a redistribution structure; a sub-package disposed on the redistribution substrate; a semiconductor chip disposed on the redistribution substrate, wherein the semiconductor chip is positioned side-by-side with the sub-package; a heat dissipation structure disposed on the redistribution substrate and surrounding the sub-package and the semiconductor chip; and an encapsulant, wherein the encapsulant encapsulates the sub-package, the semiconductor chip, and the heat dissipation structure.

According to some embodiments of the present disclosure, a semiconductor package includes a redistribution substrate including a redistribution structure; a memory package disposed on the redistribution substrate; a first connector disposed between the redistribution substrate and the memory package; a system-on-chip disposed on the redistribution substrate and side-by-side with the memory package; a second connector disposed between the redistribution substrate and the system-on-chip; a heat dissipation structure disposed on the redistribution substrate and between the memory package and the system-on-chip; an encapsulant, wherein the encapsulant encapsulates the memory package, the system-on-chip, and the heat dissipation structure; a connection member that connects the redistribution substrate to a component external to the semiconductor package; and an adhesive layer connecting the redistribution substrate and the heat dissipation structure, wherein the top of the heat dissipation structure is lower than the top of memory package or the system-on-chip.

According to some embodiments of the present disclosure, a semiconductor package manufacturing method includes forming a redistribution structure on a carrier; forming a plurality of recess portions on a first surface of a wafer; bonding a first surface of the wafer to a first surface of the redistribution structure; forming a heat dissipation structure having a plurality of through openings by cutting a second surface of the wafer opposite to the first surface of the wafer, wherein the plurality of through openings expose the first surface of the redistribution structure; placing a semiconductor chip and a memory package to each of the plurality of through openings to electrically connect the semiconductor chip and the memory package to the redistribution structure; and encapsulating the semiconductor chip, the memory package, and the heat dissipation structure with an encapsulant.

### BRIEF DESCRIPTION OF THE DRAWINGS

FIG. 1 is a cross-sectional view of a semiconductor package according to an embodiment.

FIG. 2A is a perspective view of a semiconductor package according to an embodiment.

FIG. 2B is a cross-sectional view of the semiconductor package of FIG. 2A, taken along the A-A′ direction according to an embodiment.

FIG. 3 is a cross-sectional view of a redistribution substrate according to an embodiment.

FIG. 4A is a perspective view illustrating a heat dissipation structure according to an embodiment.

FIG. 4B is a cross-sectional view illustrating a heat dissipation structure according to an embodiment. FIG. 4B is a cross-sectional view illustrating the heat dissipation structure of FIG. 4A in the A-A′ direction.

FIG. 5A is a perspective view illustrating the heat dissipation structure according to an embodiment.

FIG. 5B is a cross-sectional view illustrating a heat dissipation structure according to an embodiment. FIG. 5B is a cross-sectional view illustrating the heat dissipation structure of FIG. 5A in the A-A′ direction.

FIG. 6A is a perspective view illustrating a heat dissipation structure in each step of manufacturing a heat dissipation structure of the semiconductor package according to an embodiment.

FIG. 6B is a cross-sectional view illustrating a heat dissipation structure according to an embodiment. FIG. 6B is a cross-sectional view illustrating the heat dissipation structure of FIG. 6A in the A-A′ direction.

FIG. 7A is a perspective view illustrating a heat dissipation structure according to an embodiment.

FIG. 7B is a cross-sectional view illustrating the heat dissipation structure of FIG. 7A in the A-A′ direction.

FIG. 8 is a cross-sectional view illustrating the heat dissipation structure according to an embodiment.

FIG. 9 is across-sectional view illustrating a semiconductor package manufacturing method according to an embodiment of the present disclosure.

FIG. 10 is across-sectional view illustrating a semiconductor package manufacturing method according to an embodiment of the present disclosure.

FIG. 11 is across-sectional view illustrating a semiconductor package manufacturing method according to an embodiment of the present disclosure.

FIG. 12 is across-sectional view illustrating a semiconductor package manufacturing method according to an embodiment of the present disclosure.

FIG. 13 is across-sectional view illustrating a semiconductor package manufacturing method according to an embodiment of the present disclosure.

FIG. 14 is across-sectional view illustrating a semiconductor package manufacturing method according to an embodiment of the present disclosure.

FIG. 15 is across-sectional view illustrating a semiconductor package manufacturing method according to an embodiment of the present disclosure.

### DETAILED DESCRIPTION

Hereinafter, embodiments of the present invention will be described in detail with reference to the accompanying drawing, and thus a person of an ordinary skill can easily perform it in the technical field to which the present invention belongs. The present invention may be implemented in several different forms and is not limited to embodiments described herein.

In order to clearly explain the present invention, parts irrelevant to the description are omitted, and the same reference sign is designated to the same or similar constituent elements throughout the specification.

Throughout the specification, when it is described that an element is “connected” to another element, it includes not only a case that it is “directly connected” but also a case that it is “indirectly connected” through another component. In addition, unless explicitly described to the contrary, the word “comprise”, and variations such as “comprises” or “comprising”, will be understood to imply the inclusion of stated elements but not the exclusion of any other elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, throughout the specification, the word “on” a target element will be understood to mean positioned above or below the target element, and will not necessarily be understood to mean positioned “at an upper side” based on an opposite to gravity direction.

Further, throughout the specification, the phrase “on a plane” means viewing a target portion from the top, and the phrase “on a cross-section” means viewing a cross-section formed by vertically cutting a target portion from the side.

Hereinafter, a semiconductor device according to an embodiment will be described with reference to the drawings.

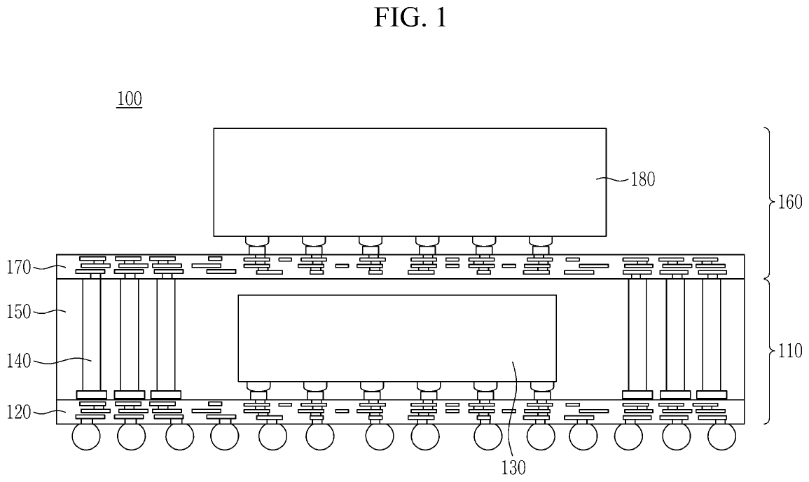

FIG. 1 is a cross-sectional view of a semiconductor package manufactured using a conventional package-on-package.

Referring to FIG. 1, a semiconductor device 100 manufacturing method is illustrated. In some examples, the manufacturing method includes disposing an upper semiconductor package 160 on a lower semiconductor package 110.

The lower semiconductor package 110 includes a redistribution substrate including a front side RDL (FRDL) 120, a semiconductor chip 130 that is disposed on the FRDL 120 and electrically coupled with the FRDL 120, and a molding material 150 that molds the semiconductor chip 130 and the metal post 140.

The upper semiconductor package 160 includes a back side redistribution layer (BRDL) 170 disposed on the lower semiconductor package 150; and a memory package 180 that is disposed on the BRDL 170 and electrically coupled with the BRDL 170. The metal post 140 of the lower semiconductor package 160 is disposed between the FRDL 120 of the lower semiconductor package 110 and the BRDL 170 of the upper semiconductor package 160 to electrically couple the FRDL 120 of the lower semiconductor package 110 and the BRDL 170 of the upper semiconductor package 160.

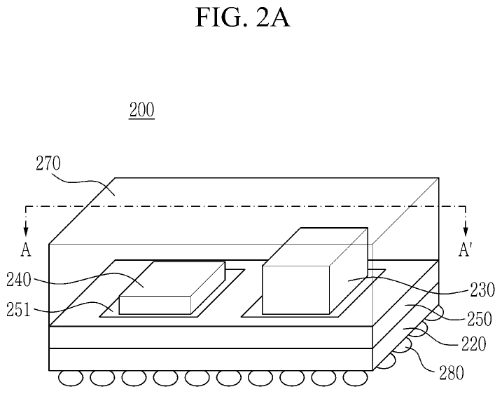

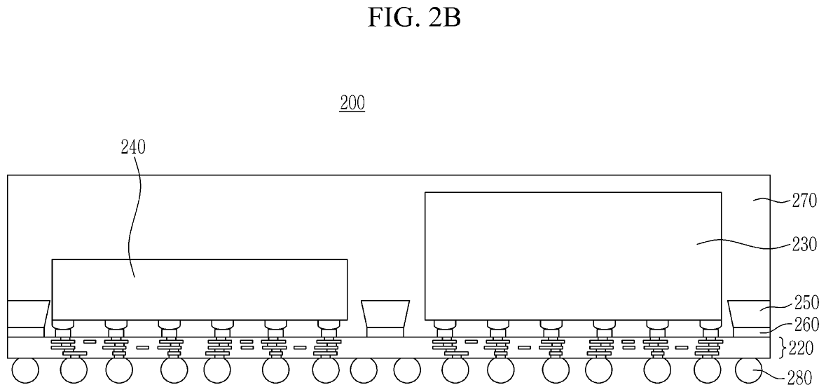

In the package-on-package method depicted in FIG. 1, the semiconductor chip 130 is molded by a material 150 that has low thermal conductivity. Additionally, the BRDL 170 and memory package 180 are located on top of the semiconductor chip. Heat generated from the semiconductor chip 130 and its wiring may not be dissipated. As a result, a thermal stress difference may arise between the upper package structure and the lower package structure, which may lead to package warpage. FIG. 2A is a perspective view of a semiconductor package 200 according to an embodiment.

Referring to FIG. 2A, embodiments of the present disclosure include a system-on-chip (SOC) 230, a memory package 240, and a heat dissipation structure 250 disposed side-by-side with the memory package 240. As shown in FIG. 2A, the SOC 230, the memory package 240, and the heat dissipation structure 250 are disposed on a redistribution substrate 220.

According to some embodiments, a system-on-chip (SOC) 230 is a semiconductor chip, and a memory package 240 is a sub-package. In some examples, the system-on-chip (SOC) 230 is disposed on the redistribution substrate 220 in a position that is adjacent to and parallel with the memory package 240, such that the system-on-chip (SOC) 230 and memory package 240 are arranged in a side-by-side configuration on the redistribution substrate 220.

The heat dissipation structure 250 includes a plurality of through openings 251. The present disclosure exemplarily illustrates a 1×2 format of through openings, but is not limited to the 1×2 format. Other formats, including through openings of fewer or greater numbers of rows or columns, are within the scope of the present disclosure. For example, it may be a 2×3 format, or a format with a larger number of columns and rows.

The SOC 230 is disposed on the redistribution substrate 220 and electrically coupled with the redistribution substrate 220 through one through-opening of the plurality of through openings 251 of the heat dissipation structure 250. In one example, the memory package 240 is positioned within the plurality of through openings 251 in the heat dissipation structure 250 on the redistribution substrate 220. In one example, the memory package 240 is electrically connected to the redistribution substrate 220 via a through-opening that does not contain the SOC 230 The heat dissipation structure 250 surrounds the disposed SOC 230 and the memory package 240 through the through-openings. Embodiments of the present disclosure include the SOC 230 and the memory package 240, but are not limited thereto. Semiconductor chips such as non-memory chips or memory chips, single chips or multi-chips, and other semiconductor packages are included in the scope of embodiments of the present disclosure.

In some embodiments, the plurality of through openings 251 of the heat dissipation structure 250 may have a rectangle shape when viewed in a plan view. In an embodiment, the shape of the plurality of through openings 251 of the heat dissipation structure 250 is not limited to a rectangle when viewed in a plan view. In some embodiments, the through openings 251 of the heat dissipation structure 250 may have inner sidewalls of a trapezoid shape. In an embodiment, the plurality of through openings 251 of the heat dissipation structure 250 may have inner sidewalls of a rectangle shape. In an embodiment, the shape of the inner sidewall of the plurality of through openings 251 of the heat dissipation structure 250 is not trapezoid or rectangle.

The plurality of through openings 251 of the heat dissipation structure 250 may include inner sidewalls having a slope of an angle. In some embodiments, the inner sidewalls of the through openings 251 of heat dissipation structure 250 may have a slope with a constant angle from the top surface to the bottom surface of heat dissipation structure 250. In one example, the constant angle is 54.74 degrees. In an embodiment, the inner sidewall of the through openings 251 of the heat dissipation structure 250 may have a 90-degree angle from the top surface to the bottom surface of the heat dissipation structure 250.

An encapsulant 270 encapsulating the redistribution substrate 220, the SOC 230, the memory package 240, and the heat dissipation structure 250 is disposed on the redistribution substrate 220, the SOC 230, the memory package 240, and the heat dissipation structure 250. The encapsulant 270 may be a molding compound, a molding underfill, an epoxy, and/or a resin.

FIG. 2B is a cross-sectional view of the semiconductor package of FIG. 2A, taken along the A-A′ direction.

Referring to FIG. 2B, the SOC 230, the memory package 240, and the heat dissipation structure 250 are disposed on the redistribution substrate 220. The SOC 230 and the memory package 240 are each electrically connected to redistribution lines of the redistribution substrate 220. The heat dissipation structure 250 is adhered to the redistribution substrate 220 by an adhesive layer 260. In addition, the encapsulant 270 encapsulates the redistribution substrate 220, the SOC 230, the memory package 240, and the heat dissipation structure 250.

In FIG. 2B, the SOC 230 and the memory package 240 are disposed side-by-side at the same level. Compared to the package-on-package technology (e.g., refer to FIG. 1) that includes BRDL as constituent elements to electrically couple the lower SOC and the upper memory package, according to embodiments of the present disclosure, the BRDL is not disposed on the SOC 230, and the memory package 240 is disposed on a side of the SOC 230 rather than the top of the SOC 230, and thus the heat generated from the SOC 230 can be discharged more effectively.

In FIG. 2B, the heat dissipation structure 250 is disposed between the SOC 230 and the memory package 240. In one example, the heat dissipation structure 250 is disposed on the right side of the SOC 230 and on the left side of the memory package 240. In some embodiments, the heat dissipation structure 250 may be formed by a material including crystalline silicon. The heat dissipation structure 250 containing crystalline silicon serves as a heat sink or radiator that efficiently dissipates the heat generated from the semiconductor chip and each wiring inside the semiconductor package.

In general, considering that the encapsulant is formed of an epoxy material, the thermal conductivity of silicon (for example, the thermal conductivity of silicon is 83.7 W/mK) has a much larger value than the thermal conductivity of the encapsulant (e.g., the thermal conductivity of epoxy is about 0.3 W/mK).

Therefore, compared to the case where the SOC 230 and the memory package 240 are encapsulated without the heat dissipation structure 250, when the heat dissipation structure 250 is formed within the encapsulant, heat generated from the semiconductor chip and each wiring in the final semiconductor package can be effectively dissipated by the heat dissipation structure 250.

In addition, when the heat dissipation structure 250 is formed within the encapsulant, the heat dissipation structure 250 may mitigate warpage deformation caused by a difference in coefficient of thermal expansion (CTE) between the redistribution substrate 220 and the encapsulant 270.

The redistribution substrate 220 has various thermal expansion coefficients depending on the material and formation method. In some cases, the redistribution substrate 220 is formed by a metal line/via (e.g., the CTE of pure Cu=about 17×10⁻⁶/° C.) and a dielectric material layer (e.g., the CTE of a silicon oxide SiO₂ is about 0.55×10⁻⁶/° C.) and the encapsulant 270 is generally formed of an epoxy material (e.g., the CTE of epoxy resin is about 50-80×10⁻⁶/° C.), the CTE of the redistribution substrate 220 is smaller than that of the encapsulant 270. Therefore, a heat dissipation structure with a much smaller CTE value than that of the encapsulant 270, such as silicon (e.g., the CTE of silicon is about 3×10⁻⁶/° C.), is formed in the area designated for the encapsulant 270. The heat dissipation structure is then encapsulated, reducing the difference between the CTE of the encapsulant 270 and the heat dissipation structure 250, and the CTE of the redistribution substrate 220. Accordingly, warpage deformation caused by differences in thermal expansion coefficient is reduced.

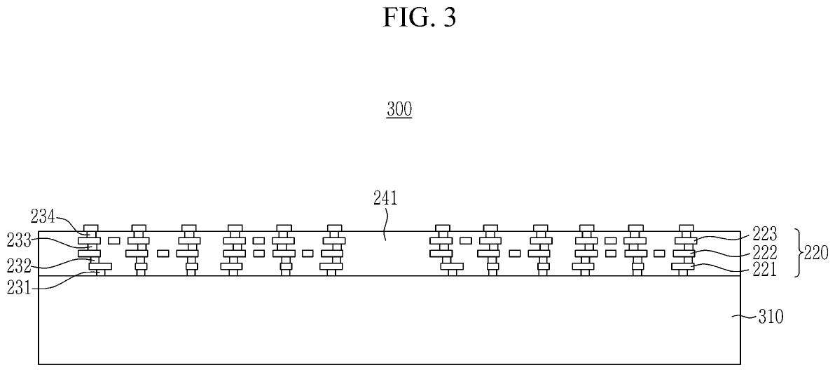

FIG. 3 to FIG. 16 illustrate a semiconductor package manufacturing method according to an embodiment of the present disclosure as an example. In the semiconductor package manufacturing method of FIG. 3 to FIG. 16, each step is performed for a wafer level package before singulation, but in FIG. 3 to FIG. 16, for convenience, only a part including the constituent elements of the wafer level package before singulation is illustrated.

FIG. 3 is a cross-sectional view of a redistribution substrate structure 300 provided in the process of the semiconductor package manufacturing method according to an embodiment.

Referring to FIG. 3, the redistribution substrate 220 containing a redistribution line is formed. First, a carrier 310 is provided. In some embodiment, the carrier 310 includes, for example, a silicon-based material such as glass or a silicon oxide, an organic material, or another material such as an aluminum oxide, any combination of these materials, and the like. The redistribution substrate 220 is formed on the carrier 310. In some embodiments, the redistribution substrate 220 includes a dielectric material layer 241, and redistribution lines 221, 222, and 223 and vias 231, 232, 233, and 234 in the dielectric material layer 241. In an embodiment, redistribution substrates containing fewer or greater numbers of redistribution lines and vias are included within the scope of embodiments of the present disclosure.

In the forming process of the redistribution substrate 220, the via 231 is formed at the bottom. The via 231 may be formed during a photoresist etching process or a hard mask etching process. In some embodiments, the via 231 may be formed of pure copper, a composition containing copper, or a copper alloy. As an embodiment, it may be formed from other materials such as aluminum or nickel. In some embodiments, the via 231 may be deposited using physical vapor deposition (PVD).

After forming the via 231, the dielectric material layer 241 is formed as high as the height of the via 231. In some embodiments, the dielectric material layer 241 is formed of a polymer such as PBO, polyimide, or the like. In some embodiments, the dielectric material layer 241 is formed of an inorganic dielectric material such as a silicon nitride, a silicon oxide, or the like. In some embodiments, the dielectric material layer 241 may be deposited through chemical vapor deposition (CVD), atomic layer deposition (ALD), plasma-enhanced chemical vapor deposition (PECVD), or other methods.

Then, an upper surface of the via 231 and the dielectric material layer 241 are planarized by applying a CMP process or mechanical grinding process.

Afterwards, the redistribution line 221—the dielectric material layer 241 as high as the redistribution line 221—the via 232—the dielectric material layer 241 as high as the via 232—the redistribution line 222—the dielectric material layer 241 as high as the redistribution line 222—the via 233—the dielectric material layer 241 as high as the via 233—the redistribution line 223—the dielectric material layer 241 as high as the redistribution line 223—the via 234—the dielectric material layer 241 as high as the via 234 are sequentially formed. The redistribution lines 221, 222, and 223, the vias 232, 233, and 234, and the dielectric material layer 241 as high as the vias 232, 233, and 234 and the vias 232, 233, and 234 in each step may be formed by applying the same forming process of the via 231 and the dielectric material layer 241 as high as the via 231.

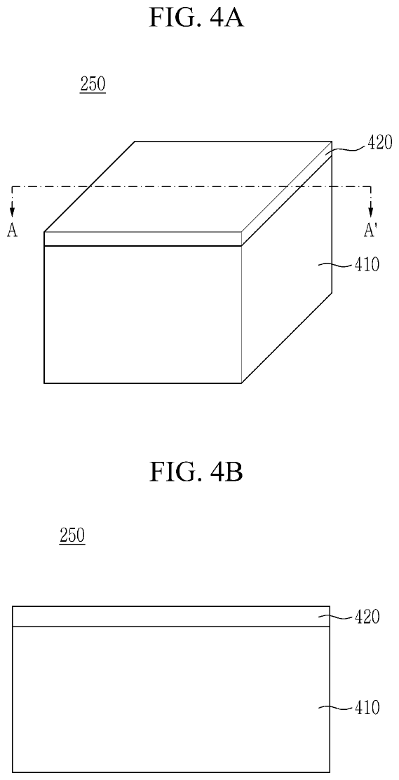

FIG. 4A to FIG. 8 illustrate the steps of the heat dissipation structure 250 manufacturing method among the steps of the semiconductor package manufacturing method according to an embodiment of the present disclosure. The heat dissipation structure 250 according to embodiments of the present disclosure includes a plurality of through openings, but FIG. 4A to FIG. 8 show the manufacturing method of one through openings.

FIG. 4A is a perspective view illustrating a heat dissipation structure in each step of manufacturing a heat dissipation structure of the semiconductor package according to an embodiment. FIG. 4B is a cross-sectional view illustrating the heat dissipation structure in each step of manufacturing the heat dissipation structure of the semiconductor package according to an embodiment.

FIG. 4B is a cross-sectional view of the heat dissipation structure in each step of manufacturing the heat dissipation structure of FIG. 4A in the A-A′ direction.

Referring to FIG. 4A and FIG. 4B, the heat dissipation structure 250 is formed using a wafer 410. In some embodiments, the wafer 410 is a non-pattern wafer or a bare wafer. In some embodiments, the wafer 410 may be formed by a material including crystalline silicon. The wafer 410 includes a first surface and a second surface positioned on the opposite side of the first surface. An etching protective layer 420 is deposited on the first surface of the wafer 410. The etching protective layer 420 may be resistant to damages of the etching solution. In some embodiments, the etching protective layer 420 may be a silicon oxide or a silicon nitride. In some embodiments, the etching protective layer 420 may be SiO₂, SiN, and Si₃N₄. In some embodiments, the etching protective layer 420 is formed using a deposit method such as plasma enhanced chemical vapor deposition (PECVD), flowable chemical vapor deposition (FCVD), low pressure chemical vapor deposition (LPCVD), or the like.

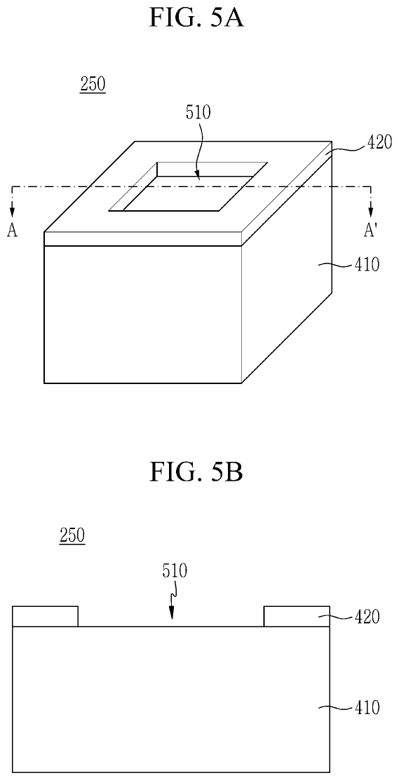

FIG. 5A is a perspective view illustrating the heat dissipation structure in each step of manufacturing the heat dissipation structure of the semiconductor package according to an embodiment. FIG. 5B is a cross-sectional view illustrating the heat dissipation structure in each step of manufacturing the heat dissipation structure of the semiconductor package according to an embodiment. FIG. 5B is a cross-sectional view of the heat dissipation structure in each step of manufacturing the heat dissipation structure of FIG. 5A in the A-A′ direction.

Referring to FIG. 5A and FIG. 5B, the etching protective layer 420 is patterned to form an opening 510. In some embodiments, the opening 510 through the patterned etching protective layer 420 may be a rectangle, but embodiments of the present disclosure are not limited thereto. In one example, the etching protective layer 420 is selectively removed in a specific pattern to create an opening 510. The pattern may be a specific shape, such as a rectangle. In one example, the pattern may match the shape of the bottom surface of a semiconductor chip to be mounted later in the process. In some embodiments, the opening 510 through the patterned etching protective layer 420 may have a shape obtained by scaling a shape of a bottom surface of a semiconductor chip to be mounted in a chip last process. An upper surface of the wafer 410 is physically exposed under the opening 510 of the patterned etching protective layer 420.

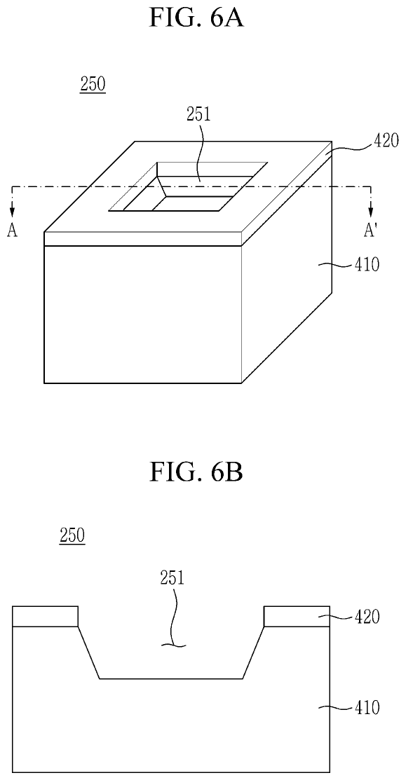

FIG. 6A is a perspective view illustrating a heat dissipation structure in each step of manufacturing a heat dissipation structure of the semiconductor package according to an embodiment. FIG. 6B is a cross-sectional view illustrating the heat dissipation structure in each step of manufacturing the heat dissipation structure of the semiconductor package according to an embodiment. FIG. 6B is a cross-sectional view of the heat dissipation structure in each step of manufacturing the heat dissipation structure of FIG. 6A in the A-A′ direction.

Referring to FIGS. 6A and 6B, an anisotropic etching process is performed on the wafer 410 through the opening 510 of the patterned etching protective layer 420. In some examples, the anisotropic etching process includes a directional etching process that selectively removes material from a substrate along specific crystal planes. In some examples, a structure with specific shapes and orientations may be formed. In some examples, a plurality of recess portions 251 may be formed on the first surface of the wafer 410 through the process. In some embodiments, an alkaline etching solution such as a KOH solution, a NaOH solution, a LiOH solution, an NH₄OH solution, or a TMAH solution may be used as the etching solution.

When an alkaline etching solution is used for crystalline silicon, crystalline silicon has different etch rates depending on the crystal orientation of silicon. The etch rate of a crystal plane or a crystal plane of silicon is higher than that on the crystal plane of silicon. When the wafer 410 made of crystalline silicon according to embodiments of the present disclosure is eroded with an alkaline etching solution, anisotropic etching is performed according to the difference in etch rate of each crystal plane for the wafer 410 exposed to the opening 510 of the etching protective layer 420, and then an etched and exposed sidewall has a crystal plane. Accordingly, recess portions 251 having an excellent sidewall profile may be formed by performing an anisotropic etching process on the first side of the wafer 410 made of crystalline silicon according to embodiments of the present disclosure. Meanwhile, the etching protective layer 420 is hardly eroded by an alkaline etching solution.

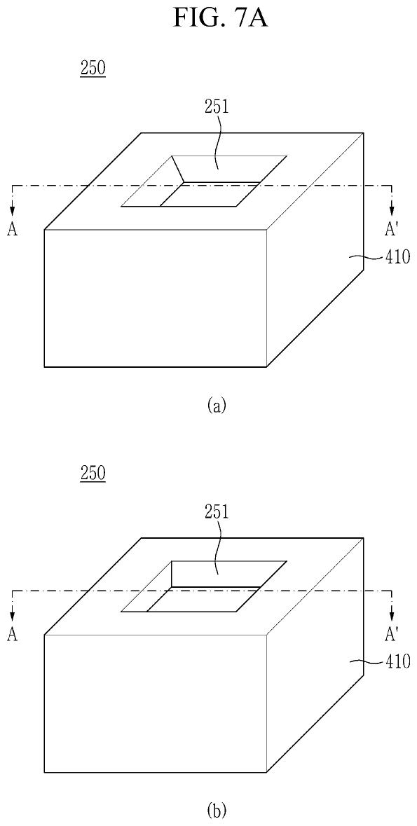

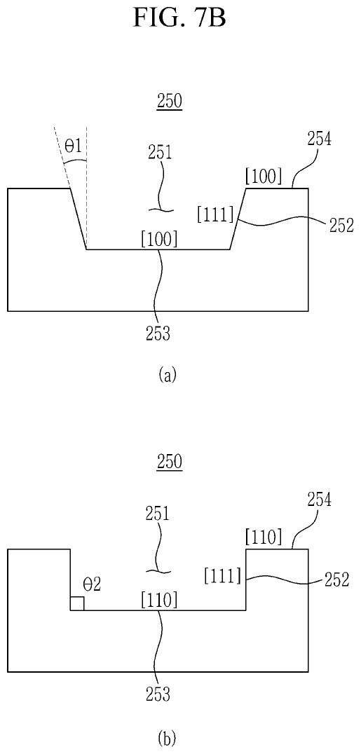

FIG. 7A is a perspective view illustrating a heat dissipation structure in each step of manufacturing a heat dissipation structure of the semiconductor package according to an embodiment. FIG. 7B is a cross-sectional view illustrating the heat dissipation structure in each step of manufacturing the heat dissipation structure of the semiconductor package according to an embodiment. FIG. 7B is a cross-sectional view of the heat dissipation structure in each step of manufacturing the heat dissipation structure of FIG. 7A in the A-A′ direction.

Referring to FIGS. 7A and 7B, the etching protective layer 420 is removed from the wafer 410 on which a plurality of recess portions 251 are formed. In some embodiments, an etching solution of an H₃PO₄ solution or a HF solution may be used to remove a silicon oxide or a silicon nitride forming the etching protective layer 420.

Embodiments of the present disclosure include bonding a first surface of the wafer to a first surface of the redistribution structure, forming a heat dissipation structure having a plurality of through openings by cutting a second surface of the wafer opposite to the first surface of the wafer, wherein the plurality of through openings expose the first surface of the redistribution structure.

In FIG. 7A and FIG. 7B, (a) shows an example in which a heat dissipation structure is manufactured using a wafer 410 including crystalline silicon having a crystal plane on the upper surface thereof. In the wafer 410 on which a plurality of recess portions 251 are formed, among the lower surface 253 of the recess portion 251 and a portion 254 of the first surface of the wafer 410 on which the recess portion 251 is not formed has a crystal plane, and the inner sidewall 252 of the recess portion 251 has a crystal plane. The inner sidewall 252 of the recess portion 251 has a predetermined slope from the lowermost end to the uppermost end. In some embodiments, a size of an angle θ1 between a direction normal to the lower surface 253 of the recess portion 251 and the inner sidewall 252 of the recess portion 251 is 35.26 degrees.

(b) shows a case in which the heat dissipation structure is manufactured using a wafer 410 including crystalline silicon having a crystal plane on the upper surface. In the wafer 410 on which a plurality of recess portions 251 are formed, among the lower surface 253 of the recess portion 251 and a portion 254 of the first surface of the wafer 410 on which the recess portion 251 is not formed has a crystal plane, and the inner sidewall of the recess portion 251 has a crystal plane. In this case, a size of the angle θ2 between the lowermost surface of the recess portion 251 and the inner sidewall of the recess portion 251 is 90 degrees.

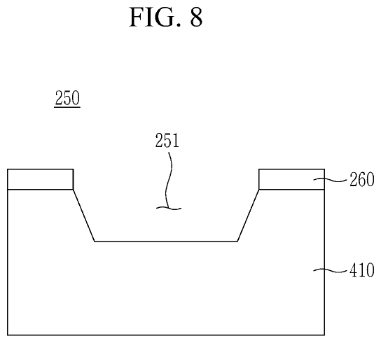

Referring to FIG. 8, an adhesive layer 260 is formed on the first surface of the wafer 410 on which the recess portion is not formed. In some embodiments, the adhesive layer 260 may be a die attach film (DAF).

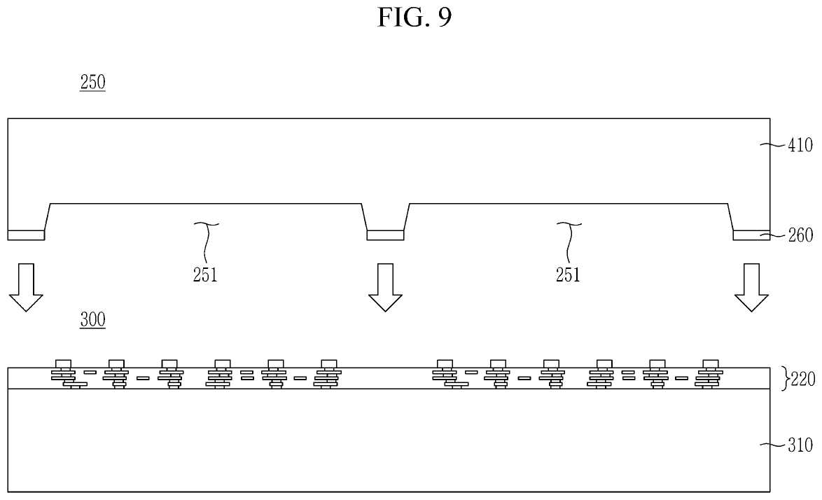

FIG. 9 to FIG. 16 are cross-sectional views that show steps of a semiconductor package manufacturing method including a heat dissipation structure 250 according to an embodiment of the present disclosure.

Referring to FIG. 9, a heat dissipation structure 250 is bonded with a redistribution substrate structure 300. A wafer 410 on which a recess portion 251 is formed is coupled to a redistribution substrate 220 on a carrier 310 using an adhesive layer 260 attached to the wafer 410.

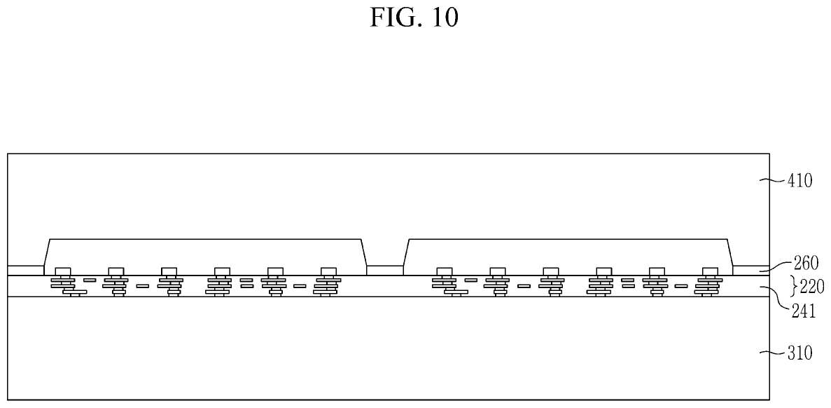

FIG. 10 shows the heat dissipation structure 250 coupled to the redistribution substrate structure 300. The adhesive layer 260 of the heat dissipation structure 250 is bonded to an upper surface of a dielectric material layer 241 of a redistribution line 221 included in the redistribution substrate 220.

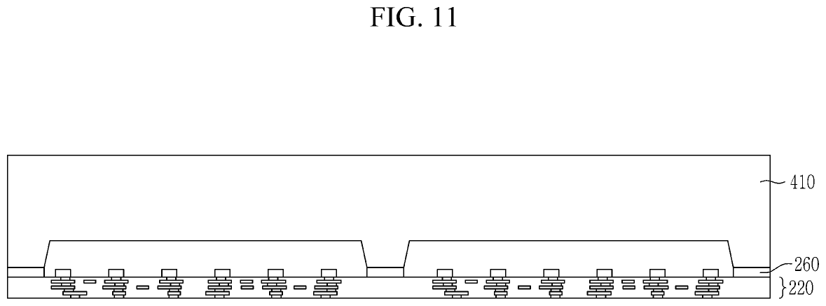

Referring to FIG. 11, after the wafer 410 of the heat dissipation structure 250 is bonded to the redistribution substrate 220, the carrier 310 is debonded from the redistribution substrate 220.

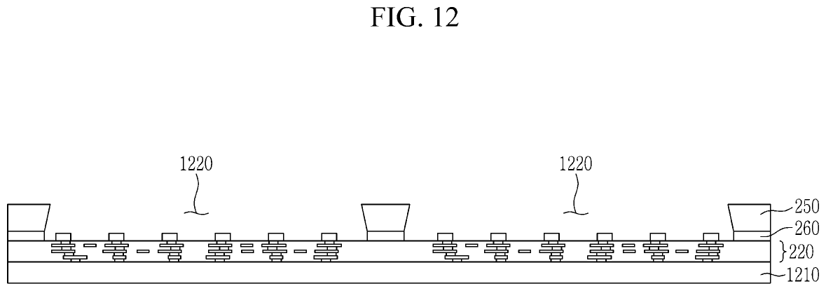

Referring to FIG. 12, a laminate film 1210 is formed on a lower surface of the redistribution substrate 220 from which the carrier 310 is debonded. The laminate film 1210 protects the redistribution substrate 220 from a manufacturing process described later. Next, a second surface of the wafer 410 of the heat dissipation structure 250 is cut to form a plurality of through openings 1220 in the heat dissipation structure 250. An upper surface of the redistribution substrate 220 is exposed through the plurality of through openings 1220. In some embodiments, the process of shaving the second surface can be performed with grinding. In some embodiments, grinding may be performed by mechanical grinding, laser, etching, or a combination thereof.

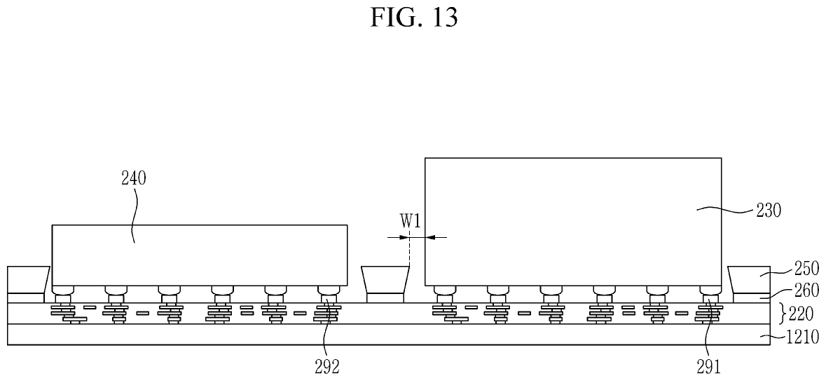

Referring to FIG. 13, an SOC 230 is disposed to one opening of the plurality of through openings 1220. The SOC 230 is electrically connected to the redistribution lines of redistribution substrate 220 by a first connector 291 positioned below the SOC 230. A memory package 240 is disposed to another opening among the plurality of through openings 1220 in which the SOC 230 is not disposed. The memory package 240 is electrically connected to the redistribution lines of the redistribution substrate 220 by a second connector 292 positioned below the memory package 240. The first connector 291 and the second connector 292 may be conductive pads. The first connector 291 and the second connector 292 are disposed between solder bumps positioned on the lower surface of the SOC 230 and the memory package 240 and the via 234 (e.g., refer to FIG. 3) of the redistribution substrate 220. Considering a bonding error that may occur when bonding with the redistribution line of the redistribution substrate 220, a distance W1 between the heat dissipation structure 250 and the SOC 230 or the memory package 240 may have a value of 15 μm or more.

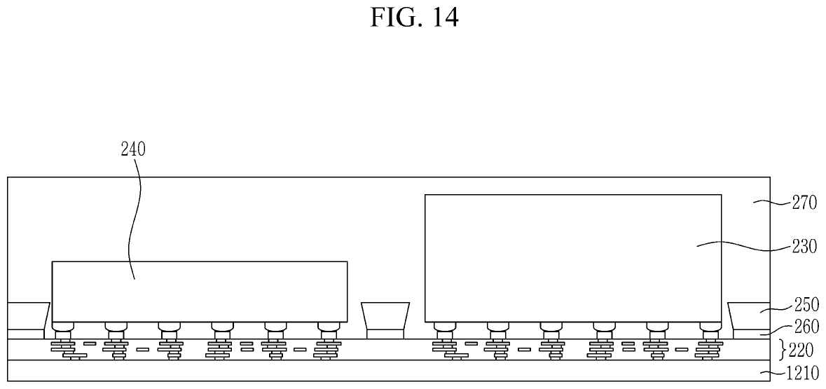

Referring to FIG. 14, the SOC 230, the memory package 240, and the heat dissipation structure 250 are encapsulated by an encapsulant 270. Encapsulation may be referred to as molding or passivation. The encapsulant 270 may surround: a space between the lower surface of the SOC 230 and the upper surface of the redistribution substrate 220; a space between the lower surface of the memory package 240 and the upper surface of the redistribution substrate 220; and side surfaces and upper surfaces of the SOC 230, the memory package 240, and the heat dissipation structure 250.

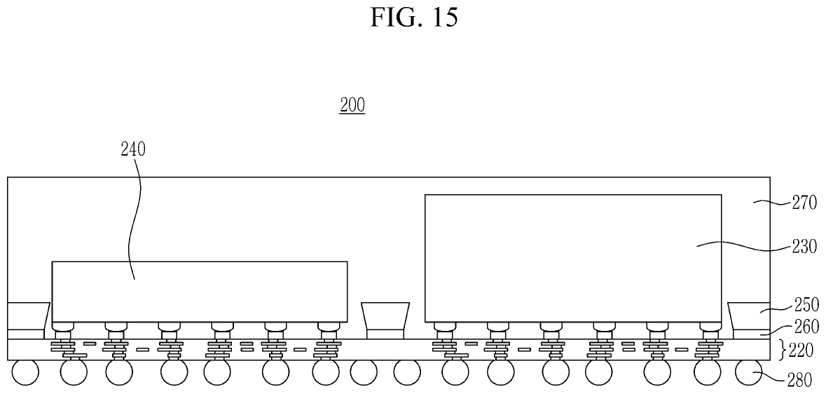

Referring to FIG. 15, the upper surface of the encapsulant 270 is cut, and a laminate film 1210 formed on the lower surface of the redistribution substrate 220 is removed. Then, a conductive connection component 280 is formed on the lower surface of the redistribution substrate 220.

While this invention has been described in connection with what is presently considered to be practical embodiments, it is to be understood that the invention is not limited to the disclosed embodiments. On the contrary, it is intended to cover modifications and equivalent arrangements included within the spirit and scope of the appended claims.

What is claimed is:

1. A semiconductor package comprising:
a redistribution substrate including a redistribution structure;
a sub-package disposed on the redistribution substrate;
a semiconductor chip disposed on the redistribution substrate, wherein the semiconductor chip is positioned side-by-side with the sub-package;
a heat dissipation structure disposed on the redistribution substrate and surrounding the sub-package and the semiconductor chip; and
an encapsulant, wherein the encapsulant encapsulates the sub-package, the semiconductor chip, and the heat dissipation structure.

2. The semiconductor package of claim 1, wherein
the heat dissipation structure is formed from a material including crystalline silicon.

3. The semiconductor package of claim 2, wherein an upper surface of the heat dissipation structure layer has a crystal plane.

4. The semiconductor package of claim 2, wherein the heat dissipation structure comprises a plurality of through openings.

5. The semiconductor package of claim 4, wherein
the sub-package is electrically connected to the redistribution structure via a first through opening of the plurality of through openings, and
the semiconductor chip is electrically connected to the redistribution structure via a second through opening of the plurality of through openings.

6. The semiconductor package of claim 4, wherein an inner sidewall of each of the plurality of through openings has a predetermined slope from a top of the through opening to a bottom of the through opening.

7. The semiconductor package of claim 4, wherein
an inner sidewall of each of the plurality of through openings has a crystal plane.

8. The semiconductor package of claim 1, wherein
the sub-package includes a memory package.

9. The semiconductor package of claim 1, wherein
a thermal expansion coefficient of the heat dissipation structure is less than a thermal expansion coefficient of the encapsulant.

10. The semiconductor package of claim 1, wherein
a thermal conductivity of the heat dissipation structure is greater than a thermal conductivity of the encapsulant.

11. A semiconductor package comprising:
a redistribution substrate including a redistribution structure;
a memory package disposed on the redistribution substrate;
a first connector disposed between the redistribution substrate and the memory package;
a system-on-chip (SOC) disposed on the redistribution substrate and side-by-side with the memory package;
a second connector disposed between the redistribution substrate and the system-on-chip;
a heat dissipation structure disposed on the redistribution substrate and between the memory package and the system-on-chip;
an encapsulant, wherein the encapsulant encapsulates the memory package, the system-on-chip, and the heat dissipation structure;
a connection member that connects the redistribution substrate to a component external to the semiconductor package; and
an adhesive layer connecting the redistribution substrate and the heat dissipation structure,
wherein the top of the heat dissipation structure is lower than the top of the memory package or the system-on-chip.

12. The semiconductor package of claim 11, wherein
a sidewall of the heat dissipation structure has a predetermined slope from a top of the through opening to a bottom of the through opening.

13. The semiconductor package of claim 11, wherein
a width of an upper surface of the heat dissipation structure is greater than a width of a lower surface of the heat dissipation structure.

14. A semiconductor package manufacturing method comprising:
forming a redistribution structure on a carrier;
forming a plurality of recess portions on a first surface of a wafer;
bonding a first surface of the wafer to a first surface of the redistribution structure;
forming a heat dissipation structure having a plurality of through openings by cutting a second surface of the wafer opposite to the first surface of the wafer, wherein the plurality of through openings expose the first surface of the redistribution structure;
placing a semiconductor chip and a memory package to each of the plurality of through openings to electrically connect the semiconductor chip and the memory package to the redistribution structure; and
encapsulating the semiconductor chip, the memory package, and the heat dissipation structure with an encapsulant.

15. The method of claim 14, wherein
the forming the plurality of recess portions on the first surface of the wafer comprises:
forming an etching protective layer on the first surface of the wafer;
forming an opening by patterning the etching protective layer;
performing an anisotropic etching process on the wafer through the opening; and
removing the etching protective layer.

16. The method of claim 14, wherein
the inner sidewall of the plurality of through openings has a predetermined slope from bottom to top.

17. The method of claim 14, further comprising: cutting through the encapsulant.

18. The method of claim 14, further comprising:
after the bonding the first surface of the wafer to the first surface of the redistribution structure,
removing the carrier from a second surface of the redistribution structure opposite to the first surface of the redistribution structure; and
laminating a protective film to the second surface of the redistribution structure.

19. The method of claim 18, further comprising: removing the protective film, and forming bump structures in a lower surface of the redistribution structure.

20. The method of claim 14, further comprising performing singulation for individual packaging.
